(19) United States
(12) Patent Application Publication
(10) Pub. No.: US 2013/0092222 A1
(43) Pub. Date: Apr. 18, 2013

(54) Nanostructured Solar Cells Utilizing Charge Plasma

(71) Applicant: NanoGrass Solar LLC, Erdenheim, PA (US)

(72) Inventor: Bahram Nabet, Erdenheim, PA (US)

(73) Assignee: NANOGRASS SOLAR LLC, Erdenheim, PA (US)

(21) Appl. No.: 13/651,531

(22) Filed: Oct. 15, 2012

Related U.S. Application Data
(60) Provisional application No. 61/547,214, filed on Oct. 14, 2011.

(51) Int. Cl. H01L 31/0352; H01L 31/0725

(52) U.S. Cl. 136/255; 257/21; 257/E31.033

(57) ABSTRACT

A device includes a generally planar substrate and a plurality of light absorbing elements extending outwardly from the substrate. Each of the light absorbing elements includes a doped outer shell, an inner core disposed inside the outer shell and a two-dimensional electron gas sheet extending and confined between the outer shell and the inner core, with a concentric cylinder of two-dimensional electron or hole gas produced in the junction between the outer shell and the inner core.

### CROSS-REFERENCE TO RELATED APPLICATION

The present application claims priority from U.S. Provisional Patent Application Ser. No. 61/547,214, entitled “Nanostructured Solar Cells with Electron Plasma”, filed on Oct. 14, 2011, which is incorporated herein in its entirety by reference.

### STATEMENT OF GOVERNMENT INTEREST

This invention was reduced to practice with Government support under Grant No. 070-2716 entitled “Detection via Collective Excitation of Confined Charge”, which was awarded by the National Science Foundation; the Government is therefore entitled to certain rights to this invention.

### FIELD OF THE INVENTION

The present invention relates to a solar cell that uses charge plasma to aid in the absorption of sunlight and in the extraction of the charge carriers that are produced in the cell so as to increase its efficiency.

### BACKGROUND OF THE INVENTION

Photovoltaic cells are well known devices that are used as an alternative form of energy generation. The cells absorb solar energy and convert that energy into electricity. While a portion of the solar energy is converted into electricity, a large remaining portion of the solar energy is reflected away from the cells and is lost, resulting in low efficiency devices. Additionally, cost factors involved in manufacturing higher efficiency solar cells have historically limited the manufacture and use of such cells.

The optical characteristics of nano wires have been the subject of intense recent examination due to the useful optical properties, such as enhanced light absorption, which makes them effective substrates for solar cells. Nano wires also show interesting photonic band gap properties and antenna like behavior, the explanation of which challenges traditional views of the interaction of light and matter in thin films of the same material. Two perspectives are often employed based on either consideration of the interaction of light with single wires, or collective, group behavior, resulting from consideration of the whole medium. The latter perspective is motivated by the strong effect of nano wires on light reflection, transmission, and absorption, with further separation into studies that consider periodicity versus those that model light scattering in non-periodic structures.

There exists a need for a high-efficiency solar cell that can be manufactured at a cost-effective rate that is suitable for large-scale production.

### BRIEF SUMMARY OF THE INVENTION

Briefly, the present invention provides a device comprising a generally planar substrate and a plurality of light absorbing elements extending outwardly from the substrate. Each of the light absorbing elements comprises a doped outer shell, an inner core disposed inside the outer shell and a two-dimensional charge gas sheet extending and confined between the outer shell and the inner core.

Additionally, the present invention also provides a solar energy cell comprising a substrate and a plurality of nano wires extending outwardly from the substrate. Each of the plurality of nano wires comprises a generally cylindrical inner core comprised of gallium arsenide. An outer shell is disposed around the inner core. The outer shell is comprised of aluminum gallium arsenide. A generally tubular two-dimensional charge gas sheet extends and is confined at the interface of the inner core and the outer shell.

Further, the present invention provides a solar cell comprising a generally planar substrate and a plurality of nano wires extending outwardly from the planar substrate. Each of the plurality of nano wires comprises an inner core and an outer shell disposed around inner core. The outer shell has a first end attached to the substrate and a second end disposed away from the substrate. A generally tubular two-dimensional charge gas sheet extends and is confined between the inner core and the outer shell. An n+ contact is affixed to the first end of the outer shell and a Schottky contact is disposed at the second end of each of the plurality of nano wires.

### BRIEF DESCRIPTION OF THE DRAWINGS

The accompanying drawings, which are incorporated herein and constitute part of this specification, illustrate the presently preferred embodiments of the invention, and, together with the general description given above and the detailed description given below, serve to explain the features of the invention. In the drawings:

FIG. 1A is a conventional GaAs substrate without nanowires (left) that is compared with an inventive GaAs substrate (right);

FIG. 1B is the measured reflectance spectrum of thin film substrates similar to FIG. 1A, (left) which shows 33% to 55% reflection of light;

FIG. 1C is the measured reflectance spectrum of nanowires with core of GaAs and shell of AlGaAs grown on both Si and GaAs substrate showing that only 3-5% of the light is reflected;

FIG. 2A is a Scanning Electron Microscope (SEM) top view of GaAs core, AlGaAs shell nanowires grown on Si substrate, showing about 15% coverage of the volume, but absorbing a factor of over 100 more light than a conventional substrate;

FIG. 2B is a SEM image of the nanowires shown in FIG. 2A, taken at a 45 degree angle;

FIG. 3 is a perspective view of a nano wire configuration on a substrate according to a first exemplary embodiment of the present invention;

FIG. 3A is a sectional view of the nano wire of FIG. 3, taken along lines 3A-3A of FIG. 3;

FIG. 4 is a perspective view of a solar cell according to an exemplary embodiment of the present invention;

FIG. 5 is a perspective view of a nano wire configuration on the substrate according to a second exemplary embodiment of the present invention;

FIG. 5A is a sectional view of the nano wire of FIG. 5, taken along lines 5A-5A of FIG. 5;

FIG. 6 is a perspective view of a nano wire configuration on the substrate according to a third exemplary embodiment of the present invention;

FIG. 6A is a sectional view of the nano wire of FIG. 6, taken along lines 6A-6A of FIG. 6;

FIG. 7 is a perspective view of a nano wire configuration on the substrate according to a fourth exemplary embodiment of the present invention;

FIG. 8 is a perspective view of a corrugated nano wire configuration according to a fifth exemplary embodiment of the present invention;

FIG. 9 is a perspective view of a nano wire configuration according to a sixth exemplary embodiment of the present invention; and

FIG. 9A is a sectional view of the nano wire of FIG. 9, taken along lines 9A-9A of FIG. 9.

### DETAILED DESCRIPTION OF THE INVENTION

In the drawings, like numerals indicate like elements throughout. Certain terminology is used herein for convenience only and is not to be taken as a limitation on the present invention. The terminology includes the words specifically mentioned, derivatives thereof and words of similar import. As used herein, the term “nano wire” is a nano structure having dimensions on the order of less than 100 nanometers in width. The embodiments illustrated below are not intended to be exhaustive or to limit the invention to the precise form disclosed. These embodiments are chosen and described to best explain the principle of the invention and its application and practical use and to enable others skilled in the art to best utilize the invention.

The present invention is a photovoltaic device, or solar cell, that is constructed using components that include a novel nanostructure for high-efficiency light absorption, which includes charge plasma for enhanced absorption and carrier collection, coupled with heteroepitaxial growth on foreign substrates. The confined charge may include electrons or holes. Further, the confined charge may be a tube of electron charge, a filament of electron charge, and may include concentric tube of electron or hole charge.

The invention includes a nanostructure array that has been designed to collectively guide light in a dielectric band for increased light energy absorption over the prior art. The inventive nanostructure can absorb more light than bulk material, partially due to larger surface to volume ratios and, as is believed by the inventor, also due to enhanced absorption.

The nanostructure array of the present invention solves the problem of the existence of a large number of surface states that eliminate absorbed photons, by growing a shell of aluminum-gallium-arsenide (AlGaAs) that lattice-matches to light absorbing gallium arsenide (GaAs) in a core. The inventive core-shell (CS) nanostructure has a plasma of free electrons at the hetero interface, which are confined to less than three dimensions, and, in an exemplary embodiment, two dimensions, resulting in useful collective properties that can be controlled by doping during growth and by generating an applied voltage after growth. The choice of AlGaAs and GaAs is exemplary and other materials such as InP, InGaAs, GaN, AlGaN, Si, SiGe, ZnO, ZnSe may substitute for the core or the shell material.

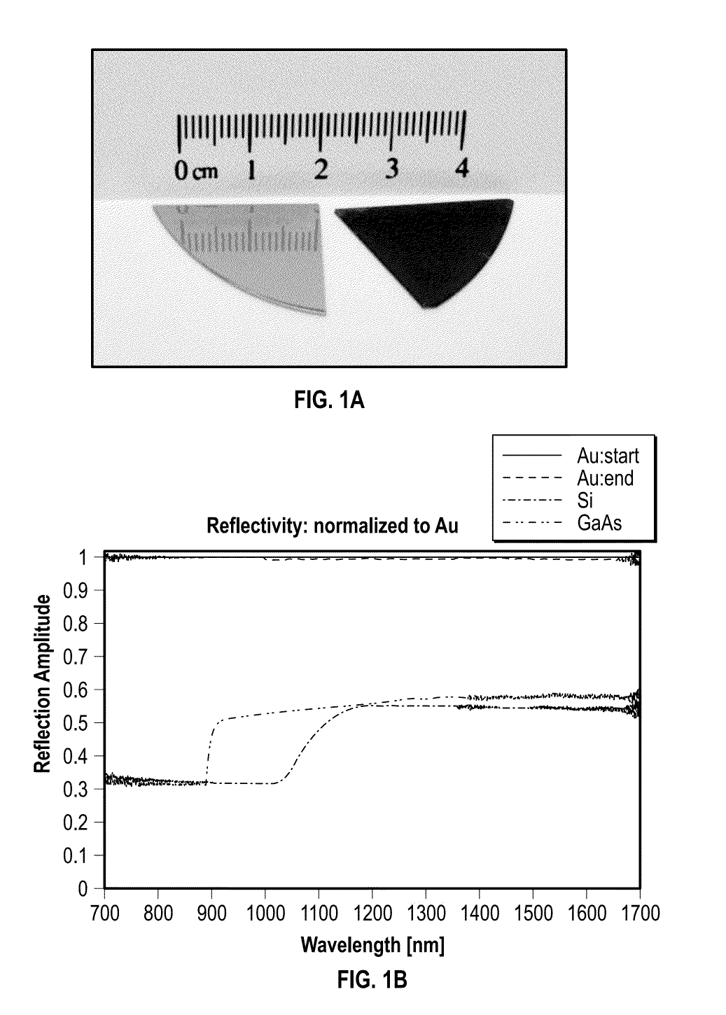

The optical characteristics of Nanowires (NWs) have been the subject of intense recent examination due to their useful optical properties, such as enhanced light absorption, which makes them effective substrates for solar cells and photodetectors. They also show interesting photonic band gap properties and antenna-like behavior, as well as strong optical emission. Two perspectives are often employed based on either consideration of the interaction of light with single wires or collective, group, behavior resulting from consideration of the whole medium. The latter perspective is motivated by the strong effect of NWs on light reflection, transmission and absorption. FIG. 1A compares a regular GaAs substrate (left) with one on which inventive NWs are grown (right). The results are striking; the former appears mirror-like reflecting the lettering, while the latter, with NWs, is almost black, showing very little reflectivity, hence high light absorption. The observed low reflectivity can be quantified by measuring the reflectance spectrum of thin film substrates, and comparing them with core-shell NWs.

FIG. 1B is the measured reflection from a normally incident light on Si, GaAs and a thin, 50 nm, layer of AlGaAs epitaxially grown on GaAs. The figure shows typical reflectivities that are in the ˜30% range which increases sharply to ˜55% for wavelengths larger than the GaAs bandage. Reflectivity spectrum of two types of GaAs/AlGaAs core-shells one grown on GaAs and the other on Si under normal incidence is measured in FIG. 1C. As observed, regardless of the substrate, the core-shells' reflectivity has the spectral shape that sharply changes above GaAs bandgap but remains in the 1-6% range for 600-1200 nm wavelength range.

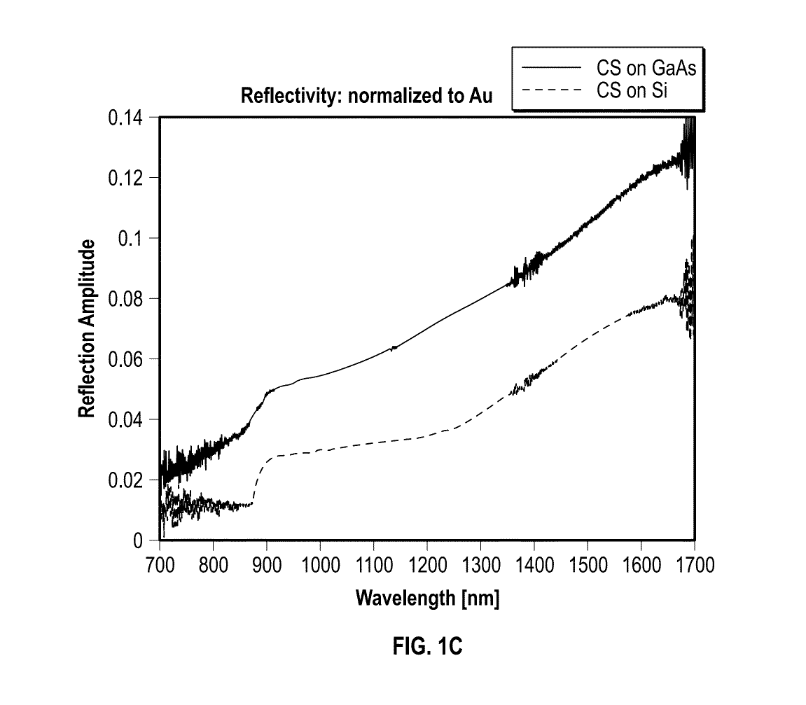

FIG. 2 is a top-view Scanning Electron Microscope (SEM) image, which shows that while the core-shell NWs occupy less than 15% of the volume compared to thin film, increase light absorption by nearly two order of magnitude. Stated differently, the same volume of CS nanowires absorbs two to three orders of magnitude more light than thin film of the same material. Furthermore, this is independent of the substrate; inventive NW's can be grown on inexpensive substrates while maintaining excellent optical and transport properties of the expensive III-V material.

Another important feature of the present invention is the existence of two-dimensional electron gas (2DEG) plasma. One effect of this 2DEG plasma is that it couples to light with a coupling strength that can be controlled by number of charge carriers and other techniques such as the addition of periodicity, thus acting as an absorber of light energy. As a result, the inventive device provides a soft plasmon-enhanced absorption process. Electron plasma also provides the inventive nano wire structures with excellent electron transport properties. Electron-hole pairs that are generated by light travel a small distance of tens of nanometers to this charge reservoir, which is much less than their momentum relaxation distance, radially, with electrons entering the plasma charge can be considered to be “collected”. As a result, these carriers need not traverse the multi-micrometer length of the wires in order to be collected by the contacts. An embodiment of the invention includes confined reservoir of hole charges which facilitate collection of optically generated holes, thus substantially increasing the efficiency of light-to-electric energy conversion.

The inventive nanostructures and devices have a transformative potential achieved by leveraging fundamental physics in order to contribute to a disruptive technological development. Further, the inventive nanostructures can be grown on a variety of substrates, such as, for example, silicon, amorphous or poly silicon, oxides, and polymers, thus substantially reducing the cost of manufacture of the inventive device.

The inventive nanostructures are based on the special properties of interaction of light with nanostructures as well as the collective optoelectronic properties of clouds of free electrons confined within such solid structures, in order to absorb light and extract electrons produced with unprecedented efficiency. These aspects are part of the basis of the inventive approach for harvesting solar energy that has a transformative potential achieved by leveraging fundamental physics but which also addresses practical issues of cost-effective manufacturability.

“Absorption” as described above refers to light that is neither transmitted nor reflected. At issue is whether the light electromagnetic energy is concentrated in the nano wires or trapped in the air between. Detailed calculations of where the electric field energy of a mode is concentrated can be performed using the electrodynamic Variational Theorem, wherein an “energy functional” is described, which is shown to be minimized for the field pattern that corresponds to the lowest frequency mode.

Referring to FIGS. 2-4, a nanostructure 100 for use with a solar cell according to an exemplary embodiment of the present invention is described. Nanostructure 100 is used to absorb solar energy and to convert the solar energy into electrical energy. Nanostructure 100 includes a generally planar substrate 110. In an exemplary embodiment, substrate 110 can be constructed from silicon, polysilicon, gallium arsenide (GaAs), indium phosphide (InP), gallium nitride (GaN), polymers, or other suitable material.

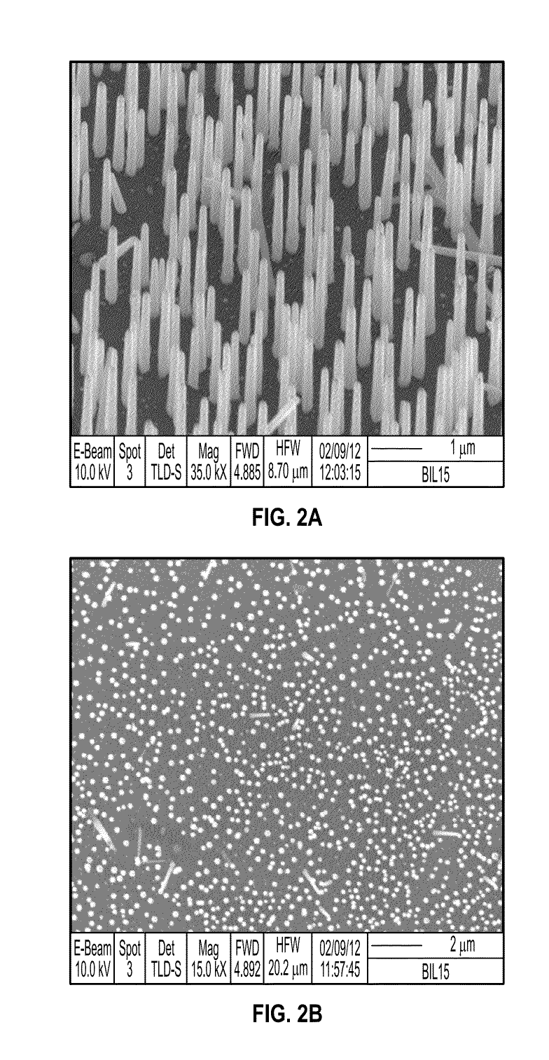

Referring to FIG. 3, a plurality of light absorbing elements in the form of nano wires 120 extend outwardly from a top surface 112 of planar substrate 110. For clarity, only a single nano wire 120 is shown in FIG. 3. In an exemplary embodiment, the plurality of nano wires 120 extending orthogonally from top surface 112. Alternatively however, nano wires 120 may extend at nonorthogonal angles from top surface 112.

Further, in an exemplary embodiment, the plurality of nano wires 120 cover less than approximately 15% of the surface area of top surface 112 and in alternative exemplary embodiment, cover about 12.5% of the surface area of top surface 112.

Each nano wire 120 has a fixed end 122 that couples nano wire 120 to substrate 110 and a free end 124 that is disposed at a far end of nano wire 120 from fixed end 122. In an exemplary embodiment, each nano wire 120 has a length of between approximately 1 and approximately 5 μm and, more particularly, a length of about 2 μm. In this example, nano wire 120 has a generally cylindrical shape although, as will be discussed in detail below, inventive nano wires can have other shapes.

As shown in FIG. 3A, a cross-section of nano wire 120 that extends parallel to substrate 110 is circular in shape. Nano wire 120 includes an inner core 140, an outer shell 150, and a two-dimensional electron gas plasma sheet 160 extending and confined between inner core 140 and outer shell 150. Nano wire 120 has a maximum radius of greater than about 5 nm, but less than about 100 nm.

In an exemplary embodiment, inner core 140 is constructed from undoped GaAs, forming a nano wire with an almost constant diameter throughout its length. Alternatively, inner core 140 can be constructed from materials from Groups III-V in the Periodic Table, such as, for example, InP, GaN, as well as Si, C, SiGe, and ZnO.

Inner core 140 is grown by metal organic vapor phase epitaxy (MOVPE) on B-oriented GaAs substrates, at about 400° C. by a known Au-catalyst assisted Vapor Liquid Solid (VLS) method using colloidal gold nanoparticles 142. In an exemplary embodiment, inner core 140 has a generally circular cross-section.

An exemplary outer shell 150 is constructed from AlGaAs with a suitable mole fraction that lattice-matches to and is overgrown around inner core 140 by conventional MOVPE or metal organic chemical vapor deposition (MOCVD) with a thickness of between about 30 and about 40 nm. More desirably, outer shell 150 has a thickness of ranging between about 5 nm and about 20 nm. Outer shell 150 may be constructed from AlGaAs, GaAsP, and generally all material systems used in High Electron Mobility Transistors (HEMT). In an exemplary embodiment, outer shell 150 has a generally cylindrical cross-section.

A 2DEG sheet 160 extends and is confined between inner core 140 and outer shell 150. This confined charge plasma is produced by doping the shell with suitable n-type or p-type dopants, producing 2DEG, and two-dimensional hole gas (2DHG) at the core/shell interface, respectively. In some systems such as GaN, the 2DEG and 2DHG are produced due to local strain, without intentional doping. Each Sheet 160 is wrapped around inner core 140 to form a generally cylindrical shape around inner core 140. Optionally, metallic quantum dots 170 may be added to outer shell 150 for surface plasmon resonance absorption enhancement of light. In an exemplary embodiment, quantum dots 170 may be constructed from zinc oxide, silicon, gold, or other suitable material.

The 2DEG and 2DHG have the primary purpose of efficiently collecting electron and holes that absorption of light generates. In addition, these electron and hole plasma directly interact with electromagnetic radiation such as light. This interaction is known as polarizability, and depends on a plasma frequency, ωₚ, which dictates coupling conditions between nano wire 120 and substrate 110. Plasma frequency is defined as:

ωₚ=\sqrt{q²n/κ_{S}∈₀}

q=electron charge (1.6×10⁻¹⁹ volts)

n=number of free electrons

κ_{S}=dielectric constant

∈₀=permittivity of free space

At plasma frequency, electrical and magnetic radiation couples strongly to the 2D GaAs. That is, at such a frequency, the 2DEG sheet directly absorbs light. As the above equation shows, the plasma frequency is proportional to the number of free electrons, hence by controlling this number by doping, or by application of a voltage, the response to radiation, may be tuned.

A layer 115 of n+ doping is produced so that an Ohmic contact on substrate 110 may be constructed. The Ohmic contact primarily provides a means of extracting electric current that is generated by light from the device.

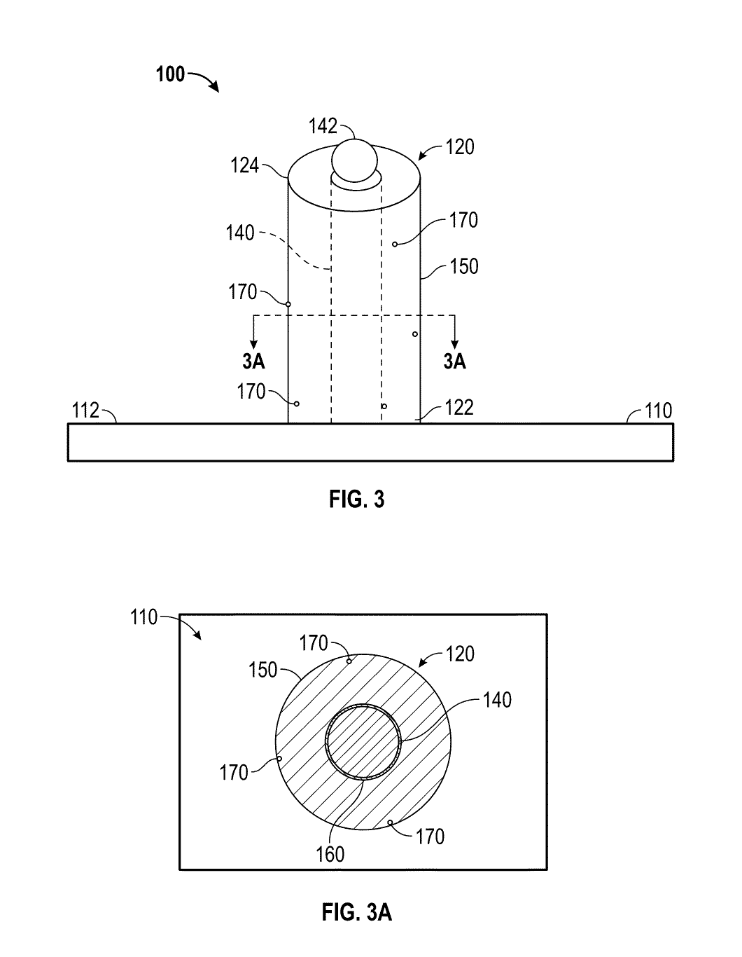

Optionally, as shown in FIG. 4, nanostructure 100 may be encapsulated in a polymer matrix 180 that also achieves planarization of a solar cell that incorporates nano structure 100. A transparent conductive oxide (TCO) layer 182 forms a contact that allows solar light to be incident from above nanostructure 100. TCO layer 182 engages free end 124 of nano wire 120. In an exemplary embodiment, TCO layer 182 may be constructed from an indium-tin-oxide compound. This contact may be Ohmic, thus producing a PN diode solar cell, or it may be a Schottky contact producing a Schottky diode solar cell. In either case the embedded 2DEG and 2DHG distinguish the present invention from all prior art.

In an exemplary embodiment, the plurality of light absorbing elements absorbs approximately 98 percent of light energy directed onto solar cell 100. The plurality of light absorbing elements have a reflectivity of less than about 1% over a wavelength of between about 400 and about 1,000 nanometers as shown in FIG. 1C.

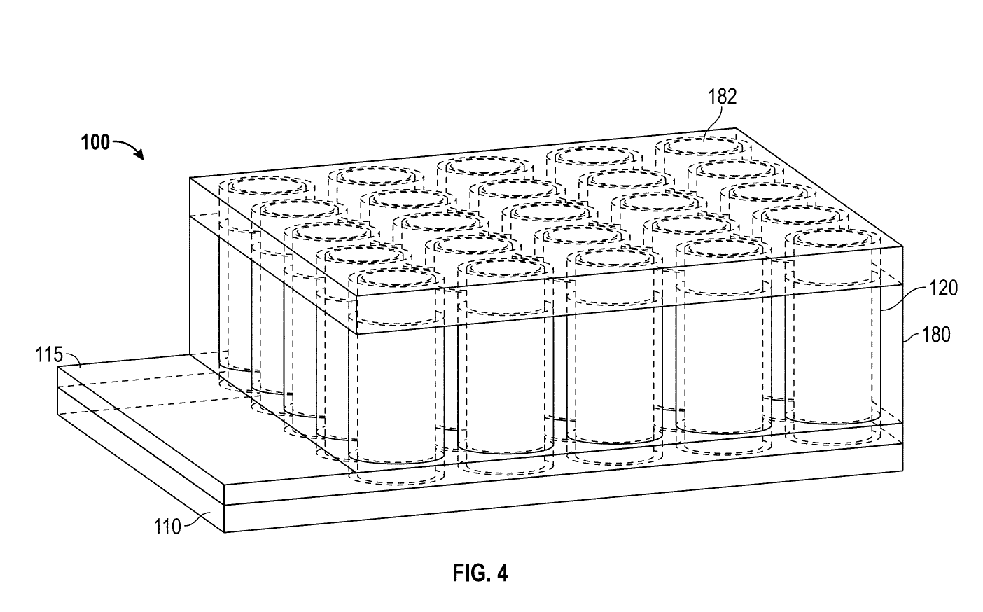

Referring to FIGS. 5-9A, a plurality of alternative embodiments of nano wires 520, 620, 720, 820, 920 may also extend from substrate 110 the same manner as nano wire 120. The alternative embodiments can provide enhanced performance and/or characteristics as a result of geometric-based resonances.

A solar cell 100 can employ a single embodiment of nano wires 120, 520, 620, 720, 820, 920, or, alternatively, a solar cell 100 can employ more than one embodiment of nano wires 120, 520, 620, 720, 820, 920. Nano wires 520, 620, 720, 820, 920 are described below and may be constructed from the same materials and have the same type of quantum dot as nano wire 120 described above, used for enhanced absorption due to surface plamson resonance. While several embodiments of inventive nano wires are described herein, those skilled in the art will recognize that other, functionally equivalent nano wires, although not specifically described in detail, are also within the scope of the present invention.

Nano wire 520 according to the present invention, shown in FIGS. 5 and 5A, has a generally conical shape, with a wider portion of nano wire 520 being a fixed end 522 that couples nano wire 520 to substrate 110. A cross-section of nano wire 520 that extends parallel to substrate 110 is also circular in shape, with the size of the circle decreasing the farther away from substrate 110 that the cross-section is taken. Nano wire 520 has an advantage of a variable cross-section that corresponds to a larger light capture cross-section than prior art devices as well as a variable exposure angle to incident light. The conical shape also takes advantage of a geometric resonance behavior within nano wire 520. This effect is described in detail in Linyou Cao et al., “Enhanced Raman scattering from individual semiconductor nanocones and nanowires,” Phys. Rev. Let. 96, 157402 (2006).

Similar to cylindrical nano wire 120, a 2DEG sheet 560 is extends and is confined between inner core 540 and outer shell 550. Sheet 560 is wrapped around inner core 540 to form a generally conical shape around inner core 540. Optionally, metallic quantum dots 570 may be added to outer shell 550 for surface plasmon resonance absorption enhancement of light.

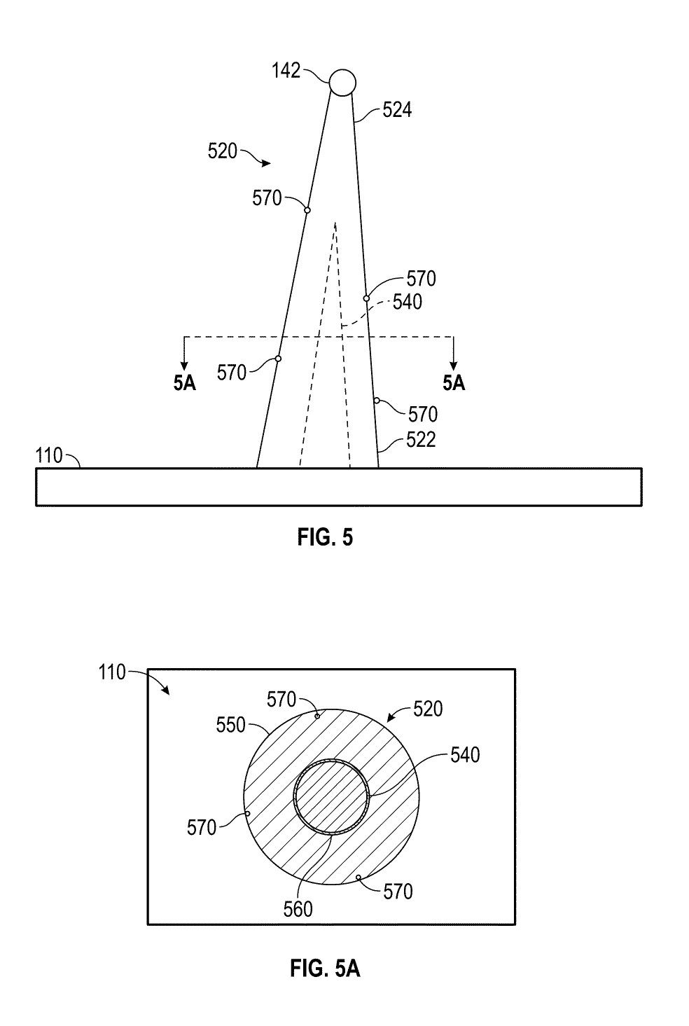

Nano wire 620 according to the present invention, shown in FIGS. 6 and 6A, has a generally faceted shape such that a cross-section of nano wire 620 that extends parallel to substrate 110 is generally faceted in shape. As shown in FIG. 6A, an inner core 640 and an outer shell 650 each have a faceted shape, with a 2DEG sheet 660 extending and confined between inner core 640 and outer shell 650. While the faceted shape shown FIGS. 6 and 6A is hexagonal, those skilled in the art will recognize that the faceted shape and the other shapes, such as, for example pentagonal, heptagonal, octagonal, etc.

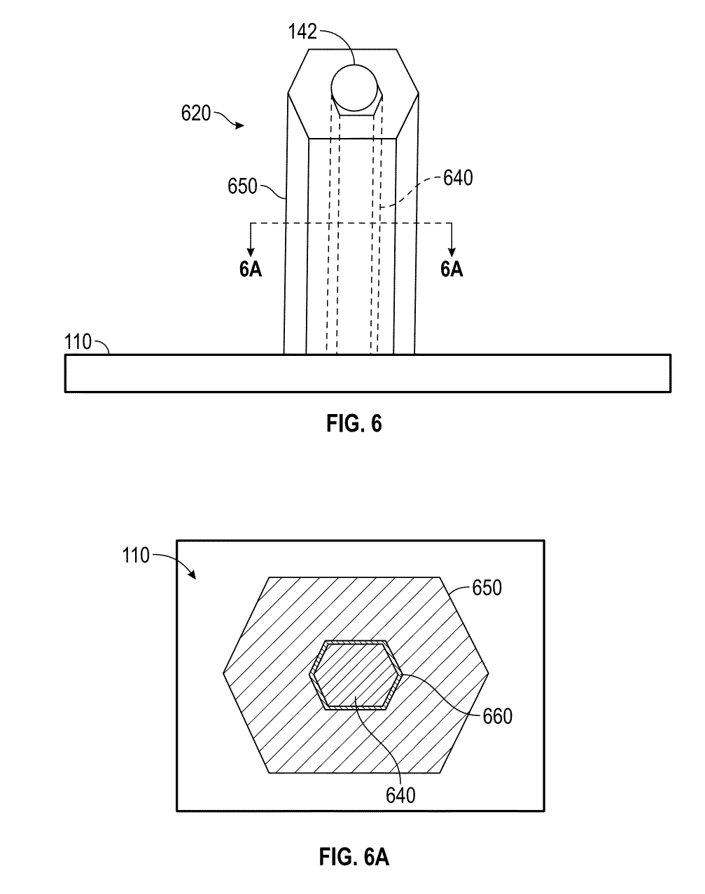

Nano wire 720 according to the present invention, shown FIG. 7, comprises a fixed end portion 722 in engagement with substrate 110 and a free end 724 having a tapered shape. For example, fixed end portion 722 may have a generally constant diameter with free end 724 extending outwardly from substrate 110 from fixed end portion 722. Optionally, all of nano wire 720 can be tapered such that the size of the generally faceted cross-section of nano wire 720, decreases as the distance of the generally faceted cross-section from substrate 110 increases. A 2DEG sheet 760 extends and is confined between inner core 740 and outer shell 750. While inner core 740 is illustrated in FIG. 7 as cylindrical, those skilled in the art will recognize that inner core 740 can be faceted instead.

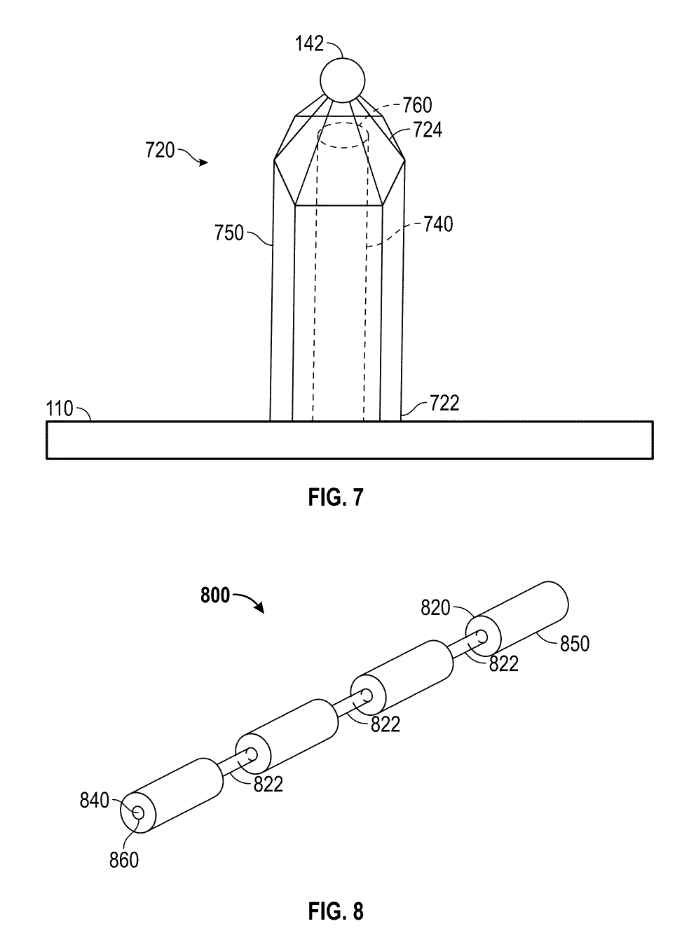

Nano wire 820 according to the present invention, shown in FIG. 8, includes periodic corrugations 822 in an outer shell 850. In an exemplary embodiment, the corrugations expose portions of an inner core 840. It is believed by the inventor that this modulation provides a delta-K vector that is needed for coupling of light into nano wire 820. While nano wire 820 is shown having a generally cylindrical outer shell 850 and a generally cylindrical inner core 840, those skilled in the art will recognize that either or both of inner core 840 and outer shell 850 can be conical, faceted, tapered, or other shape as described above with respect to nano wires 120, 520, 620, 720. A 2DEG sheet 860 extends and is confined between inner core 840 and outer shell 850. The corrugations 822 may be formed in shell 850 by etching according to known processes. The corrugations modify the charge density distribution of nano wire 820 and enhance light absorption within nano wire 820.

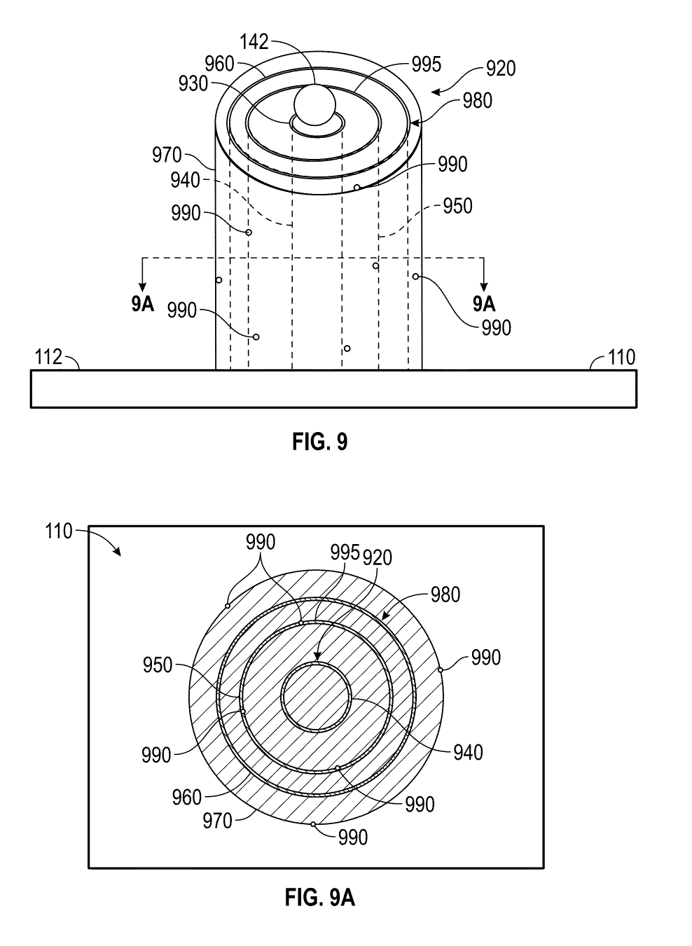

Nano wire 920 according to the present invention, shown FIGS. 9 and 9A, includes multiple concentric rings including an inner core 940, an outer shell 950 that extends radially around inner core 940, an outer core 960 that extends radially around outer shell 950, and a second shell 970 that extends radially around outer core 960. Inner core 940 and outer core 960 are both constructed from the same first material, such as, for example, gallium arsenide, while outer shell 950 and second shell 970 are both constructed from the same second material, such as, for example, aluminum gallium arsenide. Additional rings may be grown in the same manner as outer shell 150, such as by MOVPE/MOCVD or molecular Beam Epitaxy (MBE).

A first 2DEG sheet 930 extends between inner core 940 and outer shell 950 and a second 2DEG sheet 980 extends between outer core 960 and second shell 970. Each of outer shell 950 and second shell 970 may be doped with metallic quantum dots 990 to enhance light absorption. Additionally, a two-dimensional hole gas (2DHG) sheet 995 extends between outer shell 950 and outer core 960. 2DHG gas sheet 995 is separated from first 2DEG sheet 930 by between about 10 nm and about 100 nm, and 2DHG gas sheet 995 is also separated from second 2DHG gas sheet 995 by between about 10 nm and about 100 nm.

While only two layers of the first material and two layers of the second material are shown, those skilled in the art will recognize that additional layers can be formed around second shell 970, alternating the first material with the second material. Further, while nano wire 920 is shown as being formed by cylindrical cores and shells, those skilled in the art will recognize that nano wire 920 can include other shapes, including those shapes disclosed in nano wires 520, 620, 720, and 820.

Those skilled in the art will recognize that, while nanowires 120, 520, 620, 720, 820 can be used to absorb light energy for use in solar cells, nanowires 120, 520, 620, 720, 820 can also be used to emit light energy for use in Light Emitting Diodes (LED's). Nanowires 120, 520, 620, 720, 820 can also be used in terahertz radiation detectors. Nanowires 120, 520, 620, 720, 820 can also be used in detection of charges particles such as electrons or ions.

It will be appreciated by those skilled in the art that changes could be made to the embodiments described above without departing from the broad inventive concept thereof. It is understood, therefore, that this invention is not limited to the particular embodiments disclosed, but it is intended to cover modifications within the spirit and scope of the present invention as defined by the appended claims.

What is claimed is:

1. A device comprising:
(a) a generally planar substrate; and
(b) a plurality of light absorbing elements extending outwardly from the substrate, each of the light absorbing elements comprising:
(i) a doped outer shell;
(ii) an inner core disposed inside the outer shell; and
(iii) a two-dimensional charge gas sheet extending and confined between the outer shell and the inner core.

2. The device according to claim 1, wherein at least one of the plurality of light absorbing elements comprises a generally cylindrical nano wire.

3. The device according to claim 1, wherein at least one of the plurality of light absorbing elements comprises a generally conical nano wire.

4. The device according to claim 1, wherein at least one of the plurality of light absorbing elements comprises a first end in engagement with the substrate and a second end having a tapered shape.

5. The device according to claim 1, wherein at least one of the plurality of light absorbing elements has a generally faceted cross-section.

6. The device according to claim 6, wherein the size of the generally faceted cross-section decreases as the distance of the generally faceted cross-section from the substrate increases.

7. The device according to claim 1, wherein the plurality of light absorbing elements have a reflectivity of less than about 1 percent over a wavelength of between about 400 and about 1,000 nanometers.

8. The device according to claim 1, further comprising an n+ contact disposed at the substrate and a single Schottky contact disposed on each of the plurality of light absorbing elements, distal from the substrate.

9. The device according to claim 1, further comprising an outer core disposed around the outer shell.

10. The device according to claim 10, wherein the inner core is comprised of a first material and wherein the outer core is comprised of the first material.

11. The device according to claim 10, further comprising a second shell disposed around the outer core, forming a two dimensional charge gas sheet extending and confined between the second shell and the outer core.

12. The device according to claim 11, further comprising a two-dimensional charge gas sheet extending and confined between the outer shell and the outer core.

13. The device according to claim 11, wherein the outer shell is comprised of a second material and wherein the second shell is comprised of the second material.

14. The device according claim 1, wherein the outer shell comprises a plurality of radial corrugations extending outwardly from the substrate.

15. The device according to claim 14, wherein at least one of the corrugations exposes the inner core.

16. The solar cell device according claim 1, wherein the charge gas sheet comprises a generally tubular shape.

17. The device according to claim 1, wherein the substrate comprises:
a silicon substrate having a top surface;
a buffer layer disposed on the top surface; and
an n+ contact disposed on the buffer layer.

18. The device according claim 17, wherein the n+ layer forms an ohmic contact.

19. The device according to claim 1, further comprising a polymer matrix encapsulating the plurality of light absorbing elements.

20. The device according to claim 19, further comprising a transparent conductive oxide layer disposed on the polymer matrix, the transparent conductive oxide layer forming a Schottky contact with each of the light absorbing elements.

21. The device according to claim 1, wherein the device comprises a solar cell.

22. The device according to claim 1, wherein the device comprises a terahertz detector.

23. A solar cell comprising:
(a) a substrate; and
(b) a plurality of nano wires extending outwardly from the substrate, each of the plurality of nano wires comprising:
(i) a generally cylindrical inner core comprised of gallium arsenide;
(ii) an outer shell disposed around the inner core, the outer shell being comprised of aluminum gallium arsenide; and
(iii) a generally tubular two-dimensional electron gas sheet extending and confined between the inner core and the outer shell.

24. The solar cell according to claim 23, further comprising a plurality of quantum dots disposed on the outer shell.

25. A solar cell comprising:
(a) a generally planar substrate;
(b) a plurality of nano wires extending outwardly from the planar substrate, each of the plurality of nano wires comprising:
(i) an inner core;
(ii) an outer shell disposed around inner core, the outer shell having a first end attached to the substrate and a second end disposed away from the substrate; and
(iii) a generally tubular two-dimensional electron gas sheet extending and confined between the inner core and the outer shell;
(c) an n+ contact affixed to the first end of the outer shell; and
(d) a Schottky contact disposed at the second end of each of the plurality of nano wires.

26. The solar cell according to claim 25, wherein the Schottky contact comprises a transparent conductive oxide layer.

27. The solar cell according to claim 25, wherein the substrate comprises a transparent conductive oxide layer.
